(19) United States
(12) Patent Application Publication
(10) Pub. No.: US 2025/0377407 A1
(43) Pub. Date: Dec. 11, 2025

(54) SYSTEMS AND METHODS FOR IDENTIFYING INTEGRATED CIRCUIT HARDWARE BASED ON SCAN-BASED FEATURE IDENTIFIERS

(71) Applicant: University of Florida Research Foundation, Incorporated, Gainesville, FL (US)

(72) Inventors: Navid Asadi-Zanjani, Gainesville, FL (US); Chengjie Xi, Gainesville, FL (US); Hamed Dalir, Gainesville, FL (US); Nitin Varshney, Gainesville, FL (US); Mohammad Shafkat Khan, Gainesville, FL (US)

(21) Appl. No.: 19/228,080

(22) Filed: Jun. 4, 2025

Related U.S. Application Data
(60) Provisional application No. 63/658,160, filed on Jun. 10, 2024.

(51) Int. Cl. G01R 31/311; G01N 21/3586; G01N 21/95; G01R 31/28

(52) U.S. Cl. CPC G01R 31/311; G01N 21/3586; G01N 21/9501; G01R 31/2855

(57) ABSTRACT

A method and system are directed to determining one or more inspection modalities for inspecting a hardware device; receiving measurement data that is associated with the performance of one or more inspections on the hardware device based on the one or more inspection modalities; determining one or more distinguishing features based on the measurement data, wherein the one or more distinguishing features correspond to one or more hardware components of the hardware device; and generating a scan-based feature identifier for the hardware device based on the one or more distinguishing features.

### CROSS REFERENCE TO RELATED APPLICATION

This application claims the priority of U.S. Provisional Application No. 63/658,160, entitled “SYSTEMS AND METHODS FOR IDENTIFYING INTEGRATED CIRCUIT HARDWARE BASED ON SCAN-BASED FEATURE IDENTIFIERS,” filed on Jun. 10, 2024, the disclosure of which is hereby incorporated by reference in its entirety.

### TECHNICAL FIELD

Various embodiments of the present disclosure relate to semiconductor device authenticity, and more particularly to generating identifiers based on features obtained through inspection of integrated circuit hardware.

### BACKGROUND

Counterfeit integrated circuits (ICs) present a substantial risk due to their deviations in functionality, material composition, and overall specifications. Illegitimate micro-electronic products, that are mislabeled, reused, or cloned, may fall into two primary categories (i) those with functional differences (e.g., incorrect labeling or false specifications) and (ii) those that mimic original functionality yet differ in technical aspects, such as circuit timing or stress tolerance. As such, incorporating counterfeit ICs into electronic devices may lead to significant adverse effects that undermine quality, reliability, and performance.

The rise in counterfeit ICs has been linked to practices, such as outsourcing production to untrusted entities, or due to the absence of proper life cycle management or traceability framework. The detection of counterfeits may be more a viable approach than prevention as prevention may require extensive collaboration across borders, industries, and legal frameworks. Given the global nature of supply chains and the sophistication of counterfeit operations, prevention efforts may be difficult to implement and enforce consistently, while the approach of detection may offer flexibility, cost-effectiveness, and the ability to adapt to the changing tactics of counterfeiters. Despite extensive research into methods for detecting counterfeit ICs over the past decade, differentiating between new and used ICs, as well as identifying illegally produced or altered ICs, continues to be a significant challenge. The introduction of sophisticated multi-die packaging technologies may further complicate the detection of counterfeiting. For example, the combination of multiple chiplets into a single package may increase the likelihood of counterfeit components being introduced into the system. The complexity of such systems where chiplets from various sources are integrated into one package renders verifying the authenticity of each component more challenging and increases the potential for counterfeit chiplets to affect a system's overall functionality and security. Thus, given the increasing complexity and globalization of the semiconductor industry, particularly with the advent of advanced multi-die packaging techniques, there is a need for robust traceability and provenance verification mechanisms within the IC supply chain.

### BRIEF SUMMARY

Various embodiments described herein relate to methods, apparatus, systems, computing devices, computing entities, and/or the like for identifying and tracking hardware devices.

According to some embodiments, a method comprises determining one or more inspection modalities for inspecting a hardware device; receiving measurement data that is associated with the performance of one or more inspections on the hardware device based on the one or more inspection modalities; determining one or more distinguishing features based on the measurement data, wherein the one or more distinguishing features correspond to one or more hardware components of the hardware device; and generating a scan-based feature identifier for the hardware device based on the one or more distinguishing features.

In some embodiments, one or more refinements to the one or more distinguishing features are determined based on (i) a collision rate of the scan-based feature identifier with respect to another hardware device or (ii) robustness of the scan-based feature identifier with respect to one or more of aging, wear, or one or more environmental factors. In some embodiments, the one or more inspection modalities comprise terahertz imaging, thermoreflectance imaging, acoustic imaging/microscopy, 2D or 3D X-ray computed tomography, energy-dispersive X-ray spectroscopy, or Raman spectroscopy. In some embodiments, the performance of the one or more inspections comprises determining, using terahertz time-domain spectroscopy, integrated circuit packaging material characteristics associated with the hardware device. In some embodiments, the measurement data comprises imaging or spectroscopic data that is associated with a through-silicon via, a micro-bump, or a region of interest within the one or more hardware components. In some embodiments, the one or more distinguishing features comprise grain size and orientation in polycrystalline materials, defect types and densities, and variations in dopant distributions. In some embodiments, microstructural defects, material composition variations, or unique characteristics that are associated with fabrication of the hardware device are quantified. In some embodiments, determining the one or more distinguishing features comprises determining one or more layer thicknesses of the hardware device based on the measurement data; determining one or more refractive indices of the hardware device based on the measurement data; and comparing the one or more refractive indices between authentic and counterfeit samples of the hardware device. In some embodiments, determining the one or more distinguishing features comprises: generating, using an unsupervised machine learning algorithm, one or more clusters of the measurement data; and labeling the one or more distinguishing features based on authenticity associated with the one or more clusters. In some embodiments, generating the scan-based feature identifier comprises transforming the one or more distinguishing features of the hardware device into one or more unique digital signatures or fingerprints. In some embodiments, generating the scan-based feature identifier comprises generating a plurality of tiered scan-based feature identifiers for a plurality of hardware levels that are associated with the hardware device.

According to some embodiments, a system comprises one or more processors and at least one memory storing processor-executable instructions that, when executed by any of the one or more processors, causes the one or more processors to perform operations comprising determining one or more inspection modalities for inspecting a hardware device; receiving measurement data that is associated with a performance of one or more inspections on the hardware device based on the one or more inspection modalities; determining one or more distinguishing features based on the measurement data, wherein the one or more distinguishing features correspond to one or more hardware components of the hardware device; and generating a scan-based feature identifier for the hardware device based on the one or more distinguishing features.

In some embodiments, the operations further comprise determining one or more refinements to the one or more distinguishing features based on (i) a collision rate of the scan-based feature identifier with respect to another hardware device or (ii) robustness of the scan-based feature identifier with respect to one or more of aging, wear, or one or more environmental factors.

In some embodiments, the one or more inspection modalities comprise terahertz imaging, thermoreflectance imaging, acoustic imaging/microscopy, 2D or 3D X-ray computed tomography, energy-dispersive X-ray spectroscopy, or Raman spectroscopy. In some embodiments, the performance of the one or more inspections comprises determining, using terahertz time-domain spectroscopy, integrated circuit packaging material characteristics associated with the hardware device. In some embodiments, the measurement data comprises imaging or spectroscopic data that is associated with a through-silicon via, a micro-bump, or a region of interest within the one or more hardware components. In some embodiments, the one or more distinguishing features comprise grain size and orientation in polycrystalline materials, defect types and densities, and variations in dopant distributions. In some embodiments, the operations further comprise quantifying microstructural defects, material composition variations, or unique characteristics that are associated with fabrication of the hardware device. In some embodiments, to determine the one or more distinguishing features, the operations further comprise determining one or more layer thicknesses of the hardware device based on the measurement data; determining one or more refractive indices of the hardware device based on the measurement data; and comparing the one or more refractive indices between authentic and counterfeit samples of the hardware device.

According to some embodiments, one or more non-transitory computer-readable storage media including instructions that, when executed by one or more processors, cause the one or more processors to perform operations comprising determining one or more inspection modalities for inspecting a hardware device; receiving measurement data that is associated with the performance of one or more inspections on the hardware device based on the one or more inspection modalities; determining one or more distinguishing features based on the measurement data, wherein the one or more distinguishing features correspond to one or more hardware components of the hardware device; and generating a scan-based feature identifier for the hardware device based on the one or more distinguishing features.

### BRIEF DESCRIPTION OF THE DRAWINGS

Embodiments incorporating teachings of the present disclosure are shown and described with respect to the figures presented herein.

FIG. 1 depicts an example overview of an architecture in accordance with some embodiments of the present disclosure.

FIG. 2 depicts an example computing entity in accordance with some embodiments of the present disclosure.

FIG. 3 depicts an example client computing entity in accordance with some embodiments of the present disclosure.

FIG. 4 depicts a flowchart of an example process for identifying and tracking hardware devices according to some embodiments of the present disclosure.

FIG. 5 depicts an operational example of an inspection system in accordance with some embodiments of the present disclosure.

FIG. 6 depicts an operational example of scan-based feature identifiers comprising digital fingerprints that are extracted from a system-in-package in accordance with some embodiments of the present disclosure.

### DETAILED DESCRIPTION

Various embodiments of the present disclosure now will be described more fully hereinafter with reference to the accompanying drawings, in which some, but not all embodiments of the disclosure are shown. Indeed, the disclosure may be embodied in many different forms and should not be construed as limited to the embodiments set forth herein. Rather, these embodiments are provided so that this disclosure will satisfy applicable legal requirements. The term “or” is used herein in both the alternative and conjunctive sense, unless otherwise indicated. The terms “illustrative,” “example,” and “exemplary” are used to be examples with no indication of quality level. Like numbers refer to like elements throughout.

### General Overview and Example Technical Improvements

Various embodiments of the present disclosure address the challenge of validating the authenticity and integrity of hardware components, such as semiconductor chips and chiplets, which are increasingly susceptible to counterfeiting, tampering, and illicit re-distribution within the expansive and intricate supply chain networks. According to some embodiments, a framework is provided for generating scan-based feature identifiers of ICs that may be verified by physical inspection modalities.

Provenance may allow for the authentication of components at any stage of a supply chain. Buyers may verify whether an IC matches its documented history, ensuring its authenticity thereby reducing the risk of counterfeit ICs being accepted and used in critical systems. Provenance may comprise a method of identification on the die level, package level, or board level. For example, a scan-based feature identifier may be embedded into an IC, which may comprise placing physical markers on an IC package or die, storing manufacturing data in a non-volatile memory inside a chip, or inserting additional circuitry to serve as an electrical watermark such that a batch or wafer number of origin of a particular IC may be traced.

At the onset, substrates, dies, and passive or active interposer or bridge may arrive at an assembly facility, each equipped with a unique identifier. During the assembly process, such components may be combined to create an advanced IC package or system-in-package (SiP). The unique identifiers of each component may be logged and associated a resulting product, creating a traceable lineage from individual components to the final assembled package. The assembled package may then be assigned its own unique identifier, encapsulating the identity of all its constituent parts within a single reference point. Outsourced semiconductor assembly and test (OSAT) companies may link a die identifier to an identifier of a final assembled package. Linkages established by OSATs may be essential for maintaining a continuous chain of custody and providing a comprehensive audit trail from raw components to a final product.

Hardware level identifiers may serve as unique tags or codes that can be used to identify individual chips, often for purposes such as inventory management, protection against counterfeiting, and ensuring traceability throughout a chip's lifecycle. Early semiconductor ICs were identified using serial numbers and batch codes that were physically printed or etched onto the die surface or on top of the ceramic lid. The serial numbers provided a unique identifier for each chip, while batch codes helped in tracking manufacturing date and location. As technology advanced, laser engraving became a common method for adding identifiers to ICs. This method allowed for more precise and durable markings compared to ink-based methods. Laser engraving could include serial numbers, batch codes, and even simple barcodes, providing a reliable way to identify and track individual chips.

With the advent of programmable logic devices, manufacturers started using fuses and anti-fuses as a means to store unique identifiers within the chip itself. By blowing fuses in a specific pattern, a unique code may be created for each chip. Such a method was more secure than external markings, as it could not be altered without damaging the chip.

The introduction of electrically erasable programmable read-only memory (EEPROM) technology allowed for the storage of unique identifiers in a re-writable form where an identifier may be programmed into a chip during manufacturing and potentially updated later. This flexibility made EEPROM a popular choice for storing hardware level identifiers, especially in applications requiring post-manufacturing updates or recalibration.

Physically unclonable functions (PUFs) may be used to create unique signatures (e.g., digital fingerprints) that exploit minute physical variations inherent in semiconductor manufacturing. Since such variations are unpredictable and unique to each chip, PUFs may provide a highly secure and tamper-resistant way of identification. PUFs may be particularly useful for cryptographic applications and protecting against counterfeiting. However, PUFs suffer from drawbacks, such as sensitivity to environmental conditions, risk of physical degradation over time, scalability and integration challenges within manufacturing processes, challenges in enrollment and response provisioning, high resource demands for error correction, susceptibility to advanced security attacks, reliability concerns across the device's lifespan, and issues with standardization and interoperability.

Various embodiments of the present disclosure improve detection of counterfeit hardware by providing scan-based feature identifiers that can be verified by physical inspection modalities in a high reliability and high-throughput capacity. In some embodiments, scan-based feature identifiers may be implemented by exploiting manufacturing induced variations or defects in die and/or package level features that may be integrating within existing IC design and fabrication workflows. Additionally, the disclosed scan-based feature identifiers may be extracted through physical inspection, which is advantageous over traditional methods.

Several advantages are provided by the disclosed embodiments and may stem from the non-invasive nature of generating scan-based feature identifiers based on intrinsic physical characteristics of components in an IC package. Traditional security solutions, such as embedded security circuits or PUFs, require additional silicon real estate which not only increases the complexity and cost of IC design but may also impact overall chip performance and power consumption. In contrast, extracting scan-based feature identifiers through physical inspection, as disclosed in some embodiments, leverages the natural variabilities and defects present in semiconductor materials and structures themselves, without the need for additional circuitry. As such, no increase in a chip's footprint is necessary, allowing for more efficient use of the available area for the chip's primary functions.

In some embodiments, scan-based feature identifiers are derived from an IC's physical characteristics and are a result of manufacturing process and material composition, which may not be easily replicated, modeled, or removed. By contrast, traditional security measures may be reverse-engineered or bypassed through sophisticated attacks, such as modelling, cloning, man-in-the-middle, and repeat attacks. Accordingly, unique microstructural variations and defects within an IC that form a basis of an identifier, as disclosed in some embodiments, are resistant to such threats, offering a more secure and tamper-proof method of authentication.

Unlike some security solutions that require power to function (e.g., active electronic PUFs), scan-based feature identifiers, as disclosed in some embodiments, may not require an IC to be powered, which may be particularly advantageous for applications in environments where power availability is limited or for devices that are intended to operate with minimal energy consumption. Furthermore, the ability to authenticate or verify an IC without needing an electrical connection provides options for inspecting devices at various stages of the supply chain or in applications where electrical testing is impractical. Thus, the logistics of authentication may be simplified, making it possible to verify the integrity and authenticity of ICs in a broader range of contexts, including those where IC devices are not yet installed or are part of a larger, inaccessible assembly. Additionally, as provided by some embodiments of the present disclosure, given that a scan-based feature identifier may be derived from physical characteristics of an IC itself, there may not be a need to store secret keys or identifiers within a device. As such, a risk associated with potential exposure of secret data through physical or cyber-attacks may be obviated and manufacturing process may be simplified.

In some embodiments, the management of scan-based feature identifiers may not require complex key management protocols, secure storage solutions, or enrollment and provisioning of challenge response pairs given that scan-based feature identifiers are based on an IC's physical structure and can be directly obtained through inspection on-demand. Accordingly, overhead and complexity associated with managing secure scan-based feature identifiers in large-scale applications may be reduced.

Various embodiments of the present disclosure allow for the unique identification of individual dies as well as more complex assemblies, such as chiplets within a multi-chip module, interposers, and substrates. The disclosed scan-based feature identifier framework may be applied at various levels of assembly using advanced packaging techniques and heterogeneous integration where ensuring the authenticity and integrity of each component may be crucial. Moreover, individual components within a package may be tied or linked to a scan-based feature identifier that is generated on a system level and any attempt to tamper, displace, or replace components during assembly may be detected.

### Example Technical Implementation of Various Embodiments

Embodiments of the present disclosure may be implemented in various ways, including as computer program products that comprise articles of manufacture. Such computer program products may include one or more software components including, for example, software objects, methods, data structures, and/or the like. A software component may be coded in any of a variety of programming languages. An illustrative programming language may be a lower-level programming language such as an assembly language associated with a particular hardware architecture and/or operating system platform. A software component comprising assembly language instructions may require conversion into executable machine code by an assembler prior to execution by the hardware architecture and/or platform. Another example programming language may be a higher-level programming language that may be portable across multiple architectures. A software component comprising higher-level programming language instructions may require conversion to an intermediate representation by an interpreter or a compiler prior to execution.

Other examples of programming languages include, but are not limited to, a macro language, a shell or command language, a job control language, a script language, a database query or search language, and/or a report writing language. In one or more example embodiments, a software component comprising instructions in one of the foregoing examples of programming languages may be executed directly by an operating system or other software component without having to be first transformed into another form. A software component may be stored as a file or other data storage construct. Software components of a similar type or functionally related may be stored together such as, for example, in a particular directory, folder, or library. Software components may be static (e.g., pre-established, or fixed) or dynamic (e.g., created or modified at the time of execution).

A computer program product may include a non-transitory computer-readable storage medium storing applications, programs, program modules, scripts, source code, program code, object code, byte code, compiled code, interpreted code, machine code, executable instructions, and/or the like (also referred to herein as executable instructions, instructions for execution, computer program products, program code, and/or similar terms used herein interchangeably). Such non-transitory computer-readable storage media include all computer-readable media (including volatile and non-volatile media).

In one embodiment, a non-volatile computer-readable storage medium may include a floppy disk, flexible disk, hard disk, solid-state storage (SSS) (e.g., a solid-state drive (SSD), solid-state card (SSC), solid-state module (SSM)), enterprise flash drive, magnetic tape, or any other non-transitory magnetic medium, and/or the like. A non-volatile computer-readable storage medium may also include a punch card, paper tape, optical mark sheet (or any other physical medium with patterns of holes or other optically recognizable indicia), compact disc read only memory (CD-ROM), compact disc-rewritable (CD-RW), digital versatile disc (DVD), Blu-ray disc (BD), any other non-transitory optical medium, and/or the like. Such a non-volatile computer-readable storage medium may also include read-only memory (ROM), programmable read-only memory (PROM), erasable programmable read-only memory (EPROM), electrically erasable programmable read-only memory (EEPROM), flash memory (e.g., Serial, NAND, NOR, and/or the like), multimedia memory cards (MMC), secure digital (SD) memory cards, SmartMedia cards, CompactFlash (CF) cards, Memory Sticks, and/or the like. Further, a non-volatile computer-readable storage medium may also include conductive-bridging random access memory (CBRAM), phase-change random access memory (PRAM), ferroelectric random-access memory (FRAM), non-volatile random-access memory (NVRAM), magnetoresistive random-access memory (MRAM), resistive random-access memory (RRAM), Silicon-Oxide-Nitride-Oxide-Silicon memory (SONOS), floating junction gate random access memory (FJG RAM), Millipede memory, racetrack memory, and/or the like.

In one embodiment, a volatile computer-readable storage medium may include random access memory (RAM), dynamic random access memory (DRAM), static random access memory (SRAM), fast page mode dynamic random access memory (FPM DRAM), extended data-out dynamic random access memory (EDO DRAM), synchronous dynamic random access memory (SDRAM), double data rate synchronous dynamic random access memory (DDR SDRAM), double data rate type two synchronous dynamic random access memory (DDR2 SDRAM), double data rate type three synchronous dynamic random access memory (DDR3 SDRAM), Rambus dynamic random access memory (RDRAM), Twin Transistor RAM (TTRAM), Thyristor RAM (T-RAM), Zero-capacitor (Z-RAM), Rambus in-line memory module (RIMM), dual in-line memory module (DIMM), single in-line memory module (SIMM), video random access memory (VRAM), cache memory (including various levels), flash memory, register memory, and/or the like. It will be appreciated that where embodiments are described to use a computer-readable storage medium, other types of computer-readable storage media may be substituted for or used in addition to the computer-readable storage media described above.

As should be appreciated, various embodiments of the present disclosure may also be implemented as methods, apparatus, systems, computing devices, computing entities, and/or the like. As such, embodiments of the present disclosure may take the form of a data structure, apparatus, system, computing device, computing entity, and/or the like executing instructions stored on a computer-readable storage medium to perform certain steps or operations. Thus, embodiments of the present disclosure may also take the form of an entirely hardware embodiment, an entirely computer program product embodiment, and/or an embodiment that comprises a combination of computer program products and hardware performing certain steps or operations.

Embodiments of the present disclosure are described with reference to example operations, steps, processes, blocks, and/or the like. Thus, it should be understood that each operation, step, process, block, and/or the like may be implemented in the form of a computer program product, an entirely hardware embodiment, a combination of hardware and computer program products, and/or apparatus, systems, computing devices, computing entities, and/or the like carrying out instructions, operations, steps, and similar words used interchangeably (e.g., the executable instructions, instructions for execution, program code, and/or the like) on a computer-readable storage medium for execution. For example, retrieval, loading, and execution of code may be performed sequentially such that one instruction is retrieved, loaded, and executed at a time. In some example embodiments, retrieval, loading, and/or execution may be performed in parallel such that multiple instructions are retrieved, loaded, and/or executed together. Thus, such embodiments may produce specifically configured machines performing the steps or operations specified in the block diagrams and flowchart illustrations. Accordingly, the block diagrams and flowchart illustrations support various combinations of embodiments for performing the specified instructions, operations, or steps.

### Example System Architecture

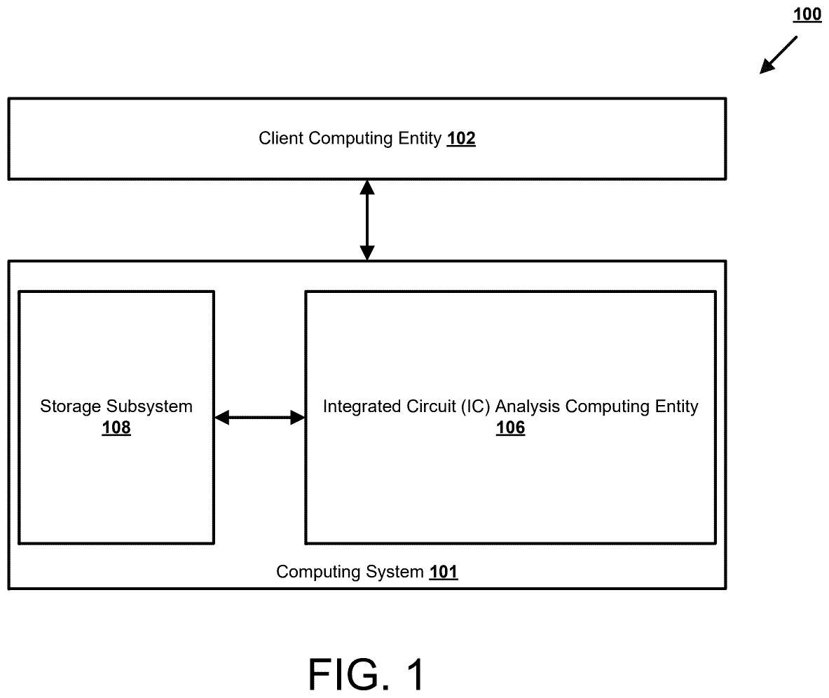

FIG. 1 depicts an example overview of an architecture 100 in accordance with some embodiments of the present disclosure. The architecture 100 includes a computing system 101 configured to receive hardware identification requests from client computing entity 102, process the hardware identification requests to generate hardware identifiers (e.g., scan-based feature identifiers), and provide the generated hardware identifiers to the client computing entity 102.

In some embodiments, computing system 101 may communicate with at least one of the client computing entity 102 using one or more communication networks. Examples of communication networks include any wired or wireless communication network including, for example, a wired or wireless local area network (LAN), personal area network (PAN), metropolitan area network (MAN), wide area network (WAN), or the like, as well as any hardware, software, and/or firmware required to implement it (such as, e.g., network routers, and/or the like).

The computing system 101 may include an IC analysis computing entity 106 and a storage subsystem 108. The IC analysis computing entity 106 may be configured to receive hardware identification requests from client computing entity 102, process the hardware identification requests to generate hardware identifiers (e.g., scan-based feature identifiers), and provide the generated hardware identifiers to the client computing entity 102. By way of example, the IC analysis computing entity 106 may be configured to train, implement, use, update, and evaluate machine learning models in accordance with one or more training and/or prediction operations of the present disclosure.

The storage subsystem 108 may be configured to store input data used by the IC analysis computing entity 106 to perform hardware identification (e.g., generate scan-based feature identifiers). For example, the storage subsystem 108 may be configured to store input data, training data, model definition data, and/or the like that may be used by the IC analysis computing entity 106 to perform predictive data analysis and/or training operations of the present disclosure. The storage subsystem 108 may include one or more storage units, such as multiple distributed storage units that are connected through a computer network. Each storage unit in the storage subsystem 108 may store at least one of one or more data assets and/or one or more data about the computed properties of one or more data assets. Moreover, each storage unit in the storage subsystem 108 may include one or more non-volatile storage or memory media including, but not limited to, hard disks, ROM, PROM, EPROM, EEPROM, flash memory, MMCs, SD memory cards, Memory Sticks, CBRAM, PRAM, FORAM, NVRAM, MRAM, RRAM, SONOS, FJG RAM, Millipede memory, racetrack memory, and/or the like.

In some example embodiments, a trained machine learning model may be provided to the IC analysis computing entity 106, which may leverage the trained machine learning model to perform one or more prediction steps/operations of the present disclosure. In some examples, feedback (e.g., evaluation data, ground truth data, etc.) from the use the of the machine learning model may be recorded by the IC analysis computing entity 106. In some examples, the feedback may be provided to the storage subsystem 108 to continuously train the machine learning model over time. In some examples, the feedback may be leveraged by the IC analysis computing entity 106 to continuously train the machine learning model over time. In this manner, the computing system 101 may perform, via one or more combinations of computing entities, one or more prediction, training, and/or any other machine learning-based techniques of the present disclosure.

### Example Data Analysis Computing Entity

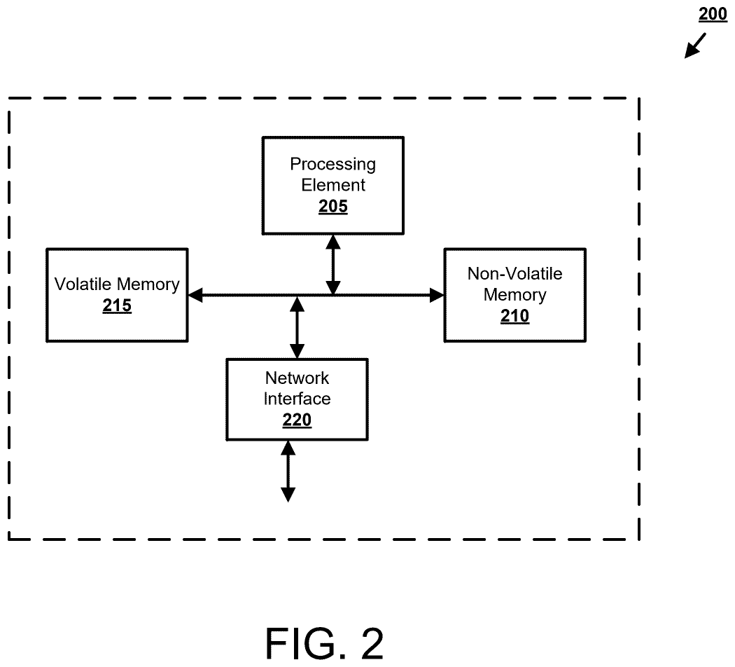

FIG. 2 depicts an example computing entity 200 in accordance with some embodiments of the present disclosure. The computing entity 200 is an example of the IC analysis computing entity 106. In general, the terms computing entity, computer, entity, device, system, and/or similar words used herein interchangeably may refer to, for example, one or more computers, computing entities, desktops, mobile phones, tablets, phablets, notebooks, laptops, distributed systems, kiosks, input terminals, servers or server networks, blades, gateways, switches, processing devices, processing entities, set-top boxes, relays, routers, network access points, base stations, the like, and/or any combination of devices or entities adapted to perform the functions, operations, and/or processes described herein. Such functions, operations, and/or processes may include, for example, transmitting, receiving, operating on, processing, displaying, storing, determining, creating/generating, monitoring, evaluating, comparing, and/or similar terms used herein interchangeably. In one embodiment, these functions, operations, and/or processes may be performed on data, content, information, and/or similar terms used herein interchangeably.

As indicated, in one embodiment, the computing entity 200 may also include one or more network interfaces 220 for communicating with various computing entities, such as by communicating data, content, information, and/or similar terms used herein interchangeably that may be transmitted, received, operated on, processed, displayed, stored, and/or the like.

As shown in FIG. 2, in one embodiment, the computing entity 200 may include, or be in communication with, one or more processing elements 205 (also referred to as processors, processing circuitry, and/or similar terms used herein interchangeably) that communicate with other elements within the computing entity 200 via a bus, for example. As will be understood, the processing elements 205 may be embodied in a number of different ways.

For example, the processing elements 205 may be embodied as one or more complex programmable logic devices (CPLDs), microprocessors, multi-core processors, coprocessing entities, application-specific instruction-set processors (ASIPs), microcontrollers, and/or controllers. Further, the processing elements 205 may be embodied as one or more other processing devices or circuitry. The term circuitry may refer to an entirely hardware embodiment or a combination of hardware and computer program products. Thus, the processing elements 205 may be embodied as integrated circuits (ICs), application specific integrated circuits (ASICs), field programmable gate arrays (FPGAs), programmable logic arrays (PLAs), hardware accelerators, other circuitry, and/or the like.

As will therefore be understood, the processing elements 205 may be configured for a particular use or configured to execute instructions stored in volatile or non-volatile media or otherwise accessible to the processing elements 205. As such, whether configured by hardware or computer program products, or by a combination thereof, the processing elements 205 may be capable of performing steps or operations according to embodiments of the present disclosure when configured accordingly.

In one embodiment, the computing entity 200 may further include, or be in communication with, non-volatile media (also referred to as non-volatile storage, memory, memory storage, memory circuitry, and/or similar terms used herein interchangeably). In one embodiment, the non-volatile storage or memory may include one or more non-volatile storage or memory media 210, including, but not limited to, hard disks, ROM, PROM, EPROM, EEPROM, flash memory, MMCs, SD memory cards, Memory Sticks, CBRAM, PRAM, FeRAM, NVRAM, MRAM, RRAM, SONOS, FJG RAM, Millipede memory, racetrack memory, and/or the like.

As will be recognized, the non-volatile storage or memory media may store databases, database instances, database management systems, data, applications, programs, program modules, scripts, source code, object code, byte code, compiled code, interpreted code, machine code, executable instructions, and/or the like. The term database, database instance, database management system, and/or similar terms used herein interchangeably may refer to a collection of records or data that is stored in a computer-readable storage medium using one or more database models, such as a hierarchical database model, network model, relational model, entity-relationship model, object model, document model, semantic model, graph model, and/or the like.

In one embodiment, the computing entity 200 may further include, or be in communication with, volatile media (also referred to as volatile storage, memory, memory storage, memory circuitry, and/or similar terms used herein interchangeably). In one embodiment, the volatile storage or memory may also include one or more volatile storage or memory media 215, including, but not limited to, RAM, DRAM, SRAM, FPM DRAM, EDO DRAM, SDRAM, DDR SDRAM, DDR2 SDRAM, DDR3 SDRAM, RDRAM, TTRAM, T-RAM, Z-RAM, RIMM, DIMM, SIMM, VRAM, cache memory, register memory, and/or the like.

As will be recognized, the volatile storage or memory media may be used to store at least portions of the databases, database instances, database management systems, data, applications, programs, program modules, scripts, source code, object code, byte code, compiled code, interpreted code, machine code, executable instructions, and/or the like being executed by, for example, the processing elements 205. Thus, the databases, database instances, database management systems, data, applications, programs, program modules, scripts, source code, object code, byte code, compiled code, interpreted code, machine code, executable instructions, and/or the like may be used to control certain aspects of the operation of the computing entity 200 with the assistance of the processing elements 205 and operating system.

As indicated, in one embodiment, the computing entity 200 may also include one or more network interfaces 220 for communicating with various computing entities, such as by communicating data, content, information, and/or similar terms used herein interchangeably that may be transmitted, received, operated on, processed, displayed, stored, and/or the like. Such communication may be executed using a wired data transmission protocol, such as fiber distributed data interface (FDDI), digital subscriber line (DSL), Ethernet, asynchronous transfer mode (ATM), frame relay, data over cable service interface specification (DOCSIS), or any other wired transmission protocol. Similarly, the computing entity 200 may be configured to communicate via wireless external communication networks using any of a variety of protocols, such as general packet radio service (GPRS), Universal Mobile Telecommunications System (UMTS), Code Division Multiple Access 2000 (CDMA2000), CDMA2000 1× (1×RTT), Wideband Code Division Multiple Access (WCDMA), Global System for Mobile Communications (GSM), Enhanced Data rates for GSM Evolution (EDGE), Time Division-Synchronous Code Division Multiple Access (TD-SCDMA), Long Term Evolution (LTE), Evolved Universal Terrestrial Radio Access Network (E-UTRAN), Evolution-Data Optimized (EVDO), High Speed Packet Access (HSPA), High-Speed Downlink Packet Access (HSDPA), IEEE 802.11 (Wi-Fi), Wi-Fi Direct, 802.16 (WiMAX), ultra-wideband (UWB), infrared (IR) protocols, near field communication (NFC) protocols, Wibree, Bluetooth protocols, wireless universal serial bus (USB) protocols, and/or any other wireless protocol.

Although not shown, the computing entity 200 may include, or be in communication with, one or more input elements, such as a keyboard input, a mouse input, a touch screen/display input, motion input, movement input, audio input, pointing device input, joystick input, keypad input, and/or the like. The computing entity 200 may also include, or be in communication with, one or more output elements (not shown), such as audio output, video output, screen/display output, motion output, movement output, and/or the like.

### Example Client Computing Entity

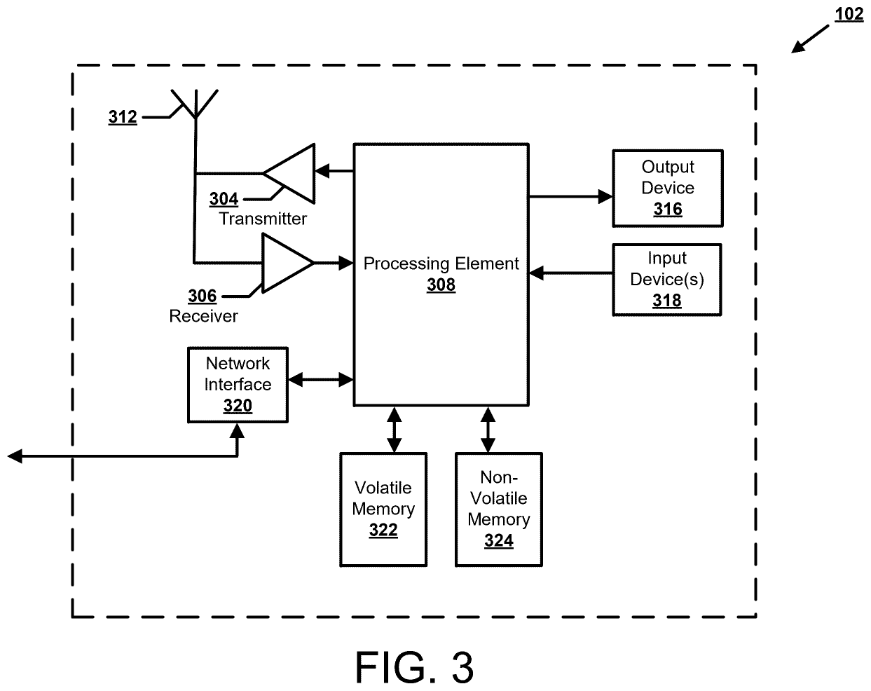

FIG. 3 depicts an example client computing entity 102 in accordance with some embodiments of the present disclosure. In general, the terms device, system, computing entity, entity, and/or similar words used herein interchangeably may refer to, for example, one or more computers, computing entities, desktops, mobile phones, tablets, phablets, notebooks, laptops, distributed systems, kiosks, input terminals, servers or server networks, blades, gateways, switches, processing devices, processing entities, set-top boxes, relays, routers, network access points, base stations, the like, and/or any combination of devices or entities adapted to perform the functions, operations, and/or processes described herein. Client computing entity 102 may be operated by various parties. As shown in FIG. 3, the client computing entity 102 may include an antenna 312, a transmitter 304 (e.g., radio), a receiver 306 (e.g., radio), and a processing element 308 (e.g., CPLDs, microprocessors, multi-core processors, coprocessing entities, ASIPs, microcontrollers, and/or controllers) that provides signals to and receives signals from the transmitter 304 and receiver 306, correspondingly.

The signals provided to and received from the transmitter 304 and the receiver 306, correspondingly, may include signaling information/data in accordance with air interface standards of applicable wireless systems. In this regard, the client computing entity 102 may be capable of operating with one or more air interface standards, communication protocols, modulation types, and access types. More particularly, the client computing entity 102 may operate in accordance with any of a number of wireless communication standards and protocols, such as those described above with regard to the computing entity 200. In a particular embodiment, the client computing entity 102 may operate in accordance with multiple wireless communication standards and protocols, such as UMTS, CDMA2000, 1×RTT, WCDMA, GSM, EDGE, TD-SCDMA, LTE, E-UTRAN, EVDO, HSPA, HSDPA, Wi-Fi, Wi-Fi Direct, WiMAX, UWB, IR, NFC, Bluetooth, USB, and/or the like. Similarly, the client computing entity 102 may operate in accordance with multiple wired communication standards and protocols, such as those described above with regard to the computing entity 200 via a network interface 320.

Via these communication standards and protocols, the client computing entity 102 may communicate with various other entities using concepts such as Unstructured Supplementary Service Data (USSD), Short Message Service (SMS), Multimedia Messaging Service (MMS), Dual-Tone Multi-Frequency Signaling (DTMF), and/or Subscriber Identity Module Dialer (SIM dialer). The client computing entity 102 may also download changes, add-ons, and updates, for instance, to its firmware, software (e.g., including executable instructions, applications, program modules), and operating system.

According to one embodiment, the client computing entity 102 may include location determining aspects, devices, modules, functionalities, and/or similar words used herein interchangeably. For example, the client computing entity 102 may include outdoor positioning aspects, such as a location module adapted to acquire, for example, latitude, longitude, altitude, geocode, course, direction, heading, speed, universal time (UTC), date, and/or various other information/data. In one embodiment, the location module may acquire data, sometimes known as ephemeris data, by identifying the number of satellites in view and the relative positions of those satellites (e.g., using global positioning systems (GPS)). The satellites may be a variety of different satellites, including Low Earth Orbit (LEO) satellite systems, Department of Defense (DOD) satellite systems, the European Union Galileo positioning systems, the Chinese Compass navigation systems, Indian Regional Navigational satellite systems, and/or the like. This data may be collected using a variety of coordinate systems, such as the DecimalDegrees (DD); Degrees, Minutes, Seconds (DMS); Universal Transverse Mercator (UTM); Universal Polar Stercographic (UPS) coordinate systems; and/or the like. Alternatively, the location information/data may be determined by triangulating the client computing entity's 102 position in connection with a variety of other systems, including cellular towers, Wi-Fi access points, and/or the like. Similarly, the client computing entity 102 may include indoor positioning aspects, such as a location module adapted to acquire, for example, latitude, longitude, altitude, geocode, course, direction, heading, speed, time, date, and/or various other information/data. Some of the indoor systems may use various position or location technologies including RFID tags, indoor beacons or transmitters, Wi-Fi access points, cellular towers, nearby computing devices (e.g., smartphones, laptops), and/or the like. For instance, such technologies may include the iBeacons, Gimbal proximity beacons, Bluetooth Low Energy (BLE) transmitters, NFC transmitters, and/or the like. These indoor positioning aspects may be used in a variety of settings to determine the location of someone or something to within inches or centimeters.

The client computing entity 102 may also comprise a user interface (that may include an output device 316 (e.g., display, speaker, tactile instrument, etc.) coupled to a processing element 308) and/or a user input interface (coupled to a processing element 308). For example, the user interface may be a user application, browser, user interface, and/or similar words used herein interchangeably executing on and/or accessible via the client computing entity 102 to interact with and/or cause display of information/data from the computing entity 200, as described herein. The user input interface may comprise any of a plurality of input devices 318 (or interfaces) allowing the client computing entity 102 to receive code and/or data, such as a keypad (hard or soft), a touch display, voice/speech or motion interfaces, or other input device. In some embodiments including a keypad, the keypad may include (or cause display of) the conventional numeric (0-9) and related keys (#, *), and other keys used for operating the client computing entity 102 and may include a full set of alphabetic keys or set of keys that may be activated to provide a full set of alphanumeric keys. In addition to providing input, the user input interface may be used, for example, to activate or deactivate certain functions, such as screen savers and/or sleep modes.

The client computing entity 102 may also include volatile storage or memory 322 and/or non-volatile storage or memory 324, which may be embedded and/or may be removable. For example, the non-volatile memory may be ROM, PROM, EPROM, EEPROM, flash memory, MMCs, SD memory cards, Memory Sticks, CBRAM, PRAM, FeRAM, NVRAM, MRAM, RRAM, SONOS, FJG RAM, Millipede memory, racetrack memory, and/or the like. The volatile memory may be RAM, DRAM, SRAM, FPM DRAM, EDO DRAM, SDRAM, DDR SDRAM, DDR2 SDRAM, DDR3 SDRAM, RDRAM, TTRAM, T-RAM, Z-RAM, RIMM, DIMM, SIMM, VRAM, cache memory, register memory, and/or the like. The volatile and non-volatile storage or memory may store databases, database instances, database management systems, data, applications, programs, program modules, scripts, source code, object code, byte code, compiled code, interpreted code, machine code, executable instructions, and/or the like to implement the functions of the client computing entity 102. As indicated, this may include a user application that is resident on the client computing entity 102 or accessible through a browser or other user interface for communicating with the computing entity 200 and/or various other computing entities.

In another embodiment, the client computing entity 102 may include one or more components or functionality that are the same or similar to those of the computing entity 200, as described in greater detail above. As will be recognized, these architectures and descriptions are provided for exemplary purposes only and are not limited to the various embodiments.

In various embodiments, the client computing entity 102 may be embodied as an artificial intelligence (AI) computing entity. Accordingly, the client computing entity 102 may be configured to provide and/or receive information/data from a user via an input/output mechanism, such as a display, a camera, a speaker, a voice-activated input, and/or the like. In certain embodiments, an AI computing entity may comprise one or more predefined and executable program algorithms stored within an onboard memory storage module, and/or accessible over a network. In various embodiments, the AI computing entity may be configured to retrieve and/or execute one or more of the predefined program algorithms upon the occurrence of a predefined trigger event.

### Example System Operations

Various embodiments of the present disclosure describe steps, operations, processes, methods, functions, and/or the like for determining physical features of hardware devices via physical inspection or imaging, interpreting patterns and/or variations in structure of the hardware devices from the physical features, and transforming the patterns and/or variations into digital signatures or fingerprints comprising scan-based feature identifiers for the hardware devices.

In some embodiments, a scan-based feature identifier comprises a data construct that describes an identifier that uniquely identifies a hardware device based on intrinsic physical characteristics of components in the hardware device. For example, a scan-based feature identifier may be generated based on physical properties of materials and interconnect structures in a hardware device, such as an IC package, that are determined via imaging or spectroscopic analysis. The manufacturing process of hardware devices may inherently introduce minute, uncontrollable variations, that are negligible in terms of performance but may be used for creating unique identification tokens. As such, unforgeable identifiers may be generated for hardware devices that are intrinsic to the hardware device itself. In some embodiments, physical inspection techniques may be used to analyze micro-structural characteristics of a die and package features to detect and quantify inherent variations and defects at a microscopic level. The micro-structural characteristics may comprise material composition, structural geometry, or parametric measurement of defects or deviation from specification. Through the analysis of the micro-structural characteristics, unique identifiers may be extracted at different abstraction levels, such as die level, package-level and wafer level.

In some embodiments, a hardware device comprises a semiconductor device, such as an IC, a system-on-chip (SoC), or a SiP, which comprise one or more chips, chiplets, and/or hardware components that are combined and mounted on an interposer and/or substrate to operate as a single system unit.

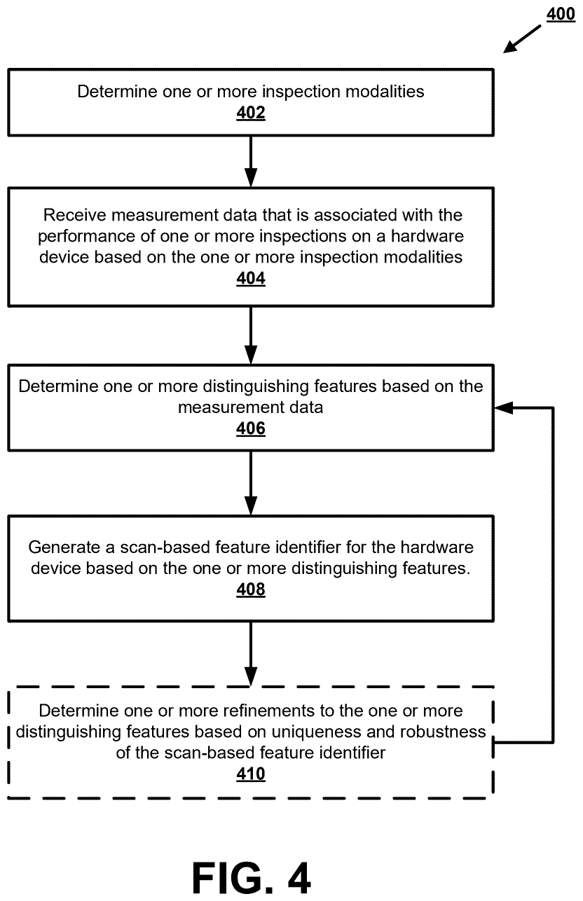

FIG. 4 depicts a flowchart of an example process 400 for identifying and tracking hardware devices according to some embodiments of the present disclosure.

In some embodiments, the process 400 begins at step/operation 402 when the computing system 101 determines one or more inspection modalities for inspecting a hardware device. In some embodiments, the one or more inspection modalities are associated with techniques for determining physical characteristics of the hardware device. In some example embodiments, determining the one or more inspection modalities may comprise selecting physical inspection modalities capable of detecting and characterizing minute, inherent variations and defects within semiconductor ICs and/or IC components within the hardware device. Inspection modalities may comprise (i) high-resolution, non-invasive imaging techniques, such as terahertz (THz) imaging, thermoreflectance imaging, acoustic imaging/microscopy, or 2D and/or 3D X-ray (computed) tomography, that are capable of visualizing microstructural characteristics of semiconductor ICs and/or IC components or (ii) spectroscopy methods, such as energy-dispersive X-ray spectroscopy (EDX) and Raman spectroscopy, that are capable of analyzing material composition and/or detecting any elemental or molecular variations.

In some embodiments, at step/operation 404, the computing system 101 receives measurement data that is associated with the performance of one or more inspections on the hardware device based on the one or more inspection modalities. According to some example embodiments, the performance of the one or more inspections comprises measuring, using terahertz time-domain spectroscopy (THz-TDS), IC packaging material characteristics of the hardware device, such as structure, material composition, and stress conditions of IC packaging encapsulants. In some embodiments, the measurement data comprises detailed imaging and spectroscopic data of specific features of interest within an IC package of the hardware device.

THz-TDS spectroscopy may comprise the use of THz signals (e.g., frequency between 0.1 THz and 10 THz) that occupy an intermediate range between microwaves and far infrared radiation. THz signals may propagate through free space, facilitating real-time scanning, and exhibit the ability to collect real-time signals with a low signal-to-noise ratio. THz signals may also penetrate common nonmetallic materials, providing higher spatial resolution and a low signal-to-noise ratio. Moreover, THz-TDS provides low energy output that does not damage sensitive hardware devices, such as memory devices, during testing.

In some embodiments, the measurement data comprises imaging and/or spectroscopic data that is associated with specific features of interest within the (package of) hardware device. For example, specific features of interest may be associated with through-silicon vias (TSVs), micro-bumps, or regions of interest within a hardware component (e.g., die or chiplet) of a package of the hardware device. In some embodiments, the measurement data may be received from one or more inspection systems that are associated with the one or more inspection modalities.

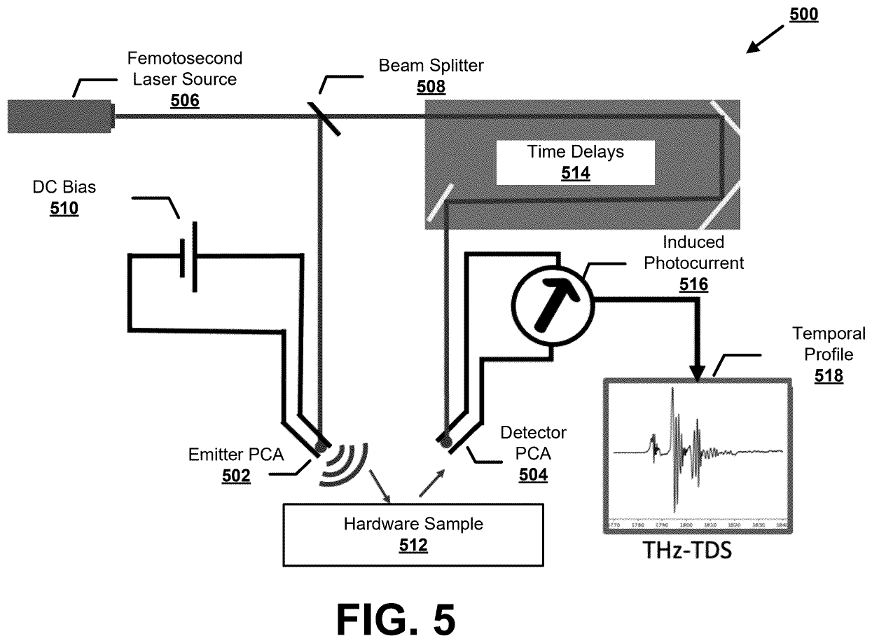

FIG. 5 depicts an operational example of an inspection system 500 in accordance with some embodiments of the present disclosure. In some embodiments, the inspection system 500 comprises a THz near-field scanning system that is configured to scan, inspect, or analyze samples of hardware devices by using THz-TDS signals. The inspection system 500 comprises an emitter photoconductive antenna (PCA) 502 that generates broadband THz pulses and a detector PCA 504 that detects broadband THz pulses. The inspection system 500 further comprises a femtosecond laser source 506 that is configured to generate femtosecond optical laser pulses that are split by a beam splitter 508 into two beams that are respectively provided to the emitter PCA 502 and the detector PCA 504. The emitter PCA 502 may comprise a direct current (DC)-biased metal dipole antenna patterned onto a photoconductive substrate.

A first femtosecond optical laser pulse split may be transmitted onto a gap between a dipole antenna of the emitter PCA 502 to generate electron-hole pairs or photocarriers. The electron-hole pairs or photocarriers may accelerate in a DC bias 510 and recombine after traveling a short distance, creating time-varying currents on a surface and are re-emitted from the emitter PCA 502 as a propagating THz pulse. To avoid delayed recombination of photocarriers and broadening of the THz pulse, photoconductive material comprising high carrier mobility and a short carrier lifetime may be used. For example, low temperature grown gallium arsenide may be used as a suitable material that comprises electron mobility that is high enough such that photocarriers generated by femtosecond optical laser pulses begin to recombine immediately after the femtosecond optical laser pulse is fully absorbed.

The operating principles of the detector PCA 504 may be similar to the emitter PCA 502, except that an external DC bias on the antenna of the detector PCA 504 comprises a bias that is applied by the THz pulses generated by the emitter PCA 502. A second femtosecond optical laser pulse (i.e., not transmitted to the emitter PCA 502) may be transmitted through a series of time delays 514 with an additional travel time of the THz pulse through a hardware sample 512 to synchronize with the detector PCA 504. When a photocarrier impulse generated by the second beam split laser pulse and the THz field overlap transiently in time, a measurable induced photocurrent 516 may be induced across the antenna of the detector PCA 504, allowing for a temporal profile 518 of a THz pulse to be determined. The inspection system 500 may provide a high signal-to-noise ratio by eliminating noise from naturally occurring sources of THz radiation that may interfere with the detector PCA.

Referring back to FIG. 4, in some embodiments, at step/operation 406, the computing system 101 determines one or more distinguishing features based on the measurement data. The one or more distinguishing features may comprise distinctive physical features that are associated with the hardware device. In some embodiments, determining the one or more distinguishing features comprises quantifying microstructural defects, material composition variations, and other unique characteristics that are associated with the fabrication of the hardware device and/or components of the hardware device. In some embodiments, the one or more distinguishing features comprise physical characteristic features, such as grain size and orientation in polycrystalline materials, defect types and densities (e.g., dislocations, vacancies), and variations in dopant distributions. In some embodiments, a distinguishing feature represents a property that corresponds to a hardware component, such as a chiplet, an interposer, and/or substrate, of the hardware device.

In some embodiments, determining the one or more distinguishing features comprises pre-processing the measurement data. Pre-processing the measurement data may enhance signal quality and remove noise from the raw measurement data such that the one or more distinguishing features may be accurately extracted from the measurement data. For example, pre-processing techniques may include, but are not limited to, filtering, contrast enhancement, and geometric corrections to ensure that the received measurement data accurately reflects physical characteristics of hardware devices. In some embodiments, a standard scaling is used to modify distinguishing features in the measurement data by subtracting the mean and dividing by the standard deviation thereby effectively standardizing each distinguishing feature, ensuring that the distinguishing features each have a mean of zero and a standard deviation of one. Standard scaling may be crucial for comparing measurements that have different units or scales. In some embodiments, L1 normalization is applied to the measurement data to adjust the measurement data so that the sum of the absolute values of each vector in the measurement data equals one. L1 normalization may be beneficial for maintaining the structure of sparse vectors, which is a common characteristic in THz-TDS data.

In some embodiments, determining one or more distinguishing features comprises determining one or more material variances associated with the hardware device. In some embodiments, determining the one or more material variances comprises determining one or more layer thicknesses of the hardware device based on the measurement data. For example, one or more layer thicknesses may be determined by measuring a distance between two different components within an IC based on X-ray imaging data and/or THz-TDS image data.

In some embodiments, determining the one or more material variances further comprises determining and comparing refractive indices of authentic and counterfeit samples of the hardware device. In one example embodiment, a near-field THz-TDS system is used to analyze authentic and counterfeit IC samples from the hardware device. For example, authentic-counterfeit pairs of IC samples comprising similar internal geometries (e.g., an epoxy, lead frame, and epoxy sandwich structure) may be positioned at similar locations to ensure that THz signal collection is consistent. In THz-TDS signal analysis, a phase change in a reflected signal may indicate an interaction with an interface that has a different relative permittivity. As such, a time delay (Δt) between two THz-TDS probes may correlate with a thickness of a tested sample as determined by the following equation:

$$d = \frac{C Δ t}{2 n} cos ( θ ) \qquad Equation 1$$

where n may represent a refractive index and C may represent the velocity of light. Given the determined one or more layer thickness of the hardware device, respective one or more refractive indices may be determined. A refractive index may be determined for each authentic or counterfeit sample and compared to determine potential material variance as a technique or method for distinguishing between authentic and counterfeit hardware devices. Additionally, the application of a deconvolution algorithm may significantly enhance signal processing that denoises the signal and aid in identifying the time delay of the THz signal, leading to more accurate thickness characterization.

In some example embodiments, determining one or more distinguishing features comprises determining one or more polymer material properties, such as crystallinity, phase transitions, and water absorption. Polymer material properties may be determined by analyzing changes in optical properties that are detected through THz-TDS signals.

In some embodiments, determining the one or more polymer material properties comprises determining an amplitude and direction of residual stress of a polymer material (of the hardware device). For example, the spectra of polymer motion may predominantly lie in the THz region, and as such, THz waves may be particularly sensitive to the orientation of polymers. Such sensitivity may allow for THz-TDS signals to be used to provide detailed insights into internal stress states of polymer materials. Accordingly, THz-TDS signals may be used to measure stress in a single direction as well assess planar stress through the analysis of collected optical properties.

According to various embodiments of the present disclosure, machine learning techniques, such as unsupervised learning algorithms, are utilized to determine one or more distinguishing features from measurement data by analyzing patterns within the measurement data, facilitating the identification of distinguishing features that may contribute most significantly to the uniqueness of a hardware device. In some example embodiments, an unsupervised machine learning model is trained to analyze measurement data (e.g., associated with pairs of authentic and counterfeit hardware device samples) for distinguishing features that may be used in counterfeit hardware device detection. For example, an unsupervised machine learning model may cluster (or generate clusters of) measurement data of hardware devices based on varying internal structures at various locations within the packages of the hardware devices. Accordingly, authentic and counterfeit hardware device samples may be associated with distinct clustering from each other based on variances in distinguishing features among the authentic and counterfeit hardware device samples as determined by an unsupervised machine learning model from the measurement data.

In accordance with various embodiments of the present disclosure, unsupervised machine learning models, such as principal component analysis (PCA), t-distributed stochastic neighbor embedding (t-SNE), or uniform manifold approximation and projection (UMAP) may be used to determine one or more distinguishing features based on measurement data. A PCA machine learning model may comprise a linear projection method that seeks a lower-dimensional subspace maximizing data variance and may be effective in uncovering patterns or identifying clusters within measurement data, if any exist. A t-SNE machine learning model may comprise a nonlinear technique that positions data points based on their similarity and may be particularly powerful at revealing local structures and clustering in high-dimensional data. A UMAP machine learning model may be similar to a t-SNE machine learning model in its non-linear approach and may excel at preserving clusters in addition to being more efficient and better able to maintain a global structure of data compared to t-SNE. Accordingly, via machine learning techniques, one or more distinguishing features and/or hardware devices may be associated with specific clusters and labeled based on authenticity (e.g., distinguishing between authentic and counterfeit hardware devices) associated with the clusters. Furthermore, the machine learning techniques may also be utilized to analyze measurement data based on other uniquely identifying classification labels.

In some embodiments, at step/operation 408, the computing system 101 generates a scan-based feature identifier for the hardware device based on the one or more distinguishing features. According to various embodiments of the present disclosure, generating the scan-based feature identifier comprises transforming patterns and/or variations based on the one or more distinguishing features of the hardware device into unique digital signatures or fingerprints. In some embodiments, generating more scan-based feature identifiers comprises transforming, using one or more cryptographic algorithms, the one or more distinguishing features into respective one or more digital signatures. In some embodiments, the one or more cryptographic algorithms comprise one-way functions that ensures the generated scan-based feature identifiers are not easily reverse-engineered to reveal specific physical characteristics, thereby protecting proprietary or sensitive information that may be associated with the hardware device. In some embodiments, the one or more cryptographic algorithms provide uniqueness and repeatability such that each scan-based feature identifier is distinct and consistently reproducible under different inspection conditions.

In some embodiments, generating the scan-based feature identifier comprises generating a plurality of tiered scan-based feature identifiers for a plurality of hardware levels (e.g., die level, package level, or board level) that are associated with the hardware devices. For example, a tiered scan-based feature identifier may be generated for (i) each lower-level component, (ii) each subsystem that comprises one or more lower-level components, and (iii) a system that comprises one or more subsystems. In some embodiments, a scan-based feature identifier that is associated with a higher hardware level may be generated based on one or more tiered scan-based feature identifiers that are associated with one or more lower hardware levels.

In some embodiments, at optional step/operation 410, the computing system 101 determines one or more refinements to the one or more distinguishing features based on uniqueness and robustness of the scan-based feature identifier. Determining the one or more refinements may comprise verifying uniqueness and stability of the scan-based feature identifier by comparing the scan-based feature identifier with scan-based feature identifiers of other hardware devices and under various operational and environmental conditions. In some embodiments, verifying uniqueness and stability of the scan-based feature identifier comprises determining (e.g., via statistical analysis) a collision rate or a likelihood of two distinct hardware devices generating a same scan-based feature identifier.

In some embodiments, determining the one or more refinements comprises determining robustness of the scan-based feature identifier with respect to aging, wear, and environmental factors (e.g., temperature variations, mechanical stress). As disclosed according to various embodiments of the present disclosure, given that scan-based feature identifiers are generated based on distinguishing features determined based on physical characteristics of hardware devices, various environment, operating, and/or stress conditions may alter the consistency and/or reliability of scan-based feature identifiers. In some embodiments, hardware devices may comprise EMC material, such as thermosetting polymers, as encapsulants and/or as an underfill material (e.g., for flip-chip packaging). The properties of EMC materials may be influenced by environmental or operating conditions. For example, environmental stress, such as moisture, thermal conditions, and physical stress, may lead to changes in both physical structure and functional performance of EMC material. Accordingly, to maintain the reliability and accuracy of scan-based feature identifiers, impact of environmental loading and stress conditions on hardware devices may be determined. Based on the determined impact, environmental loading and stress conditions effects on hardware devices may be filtered via refinements to the distinguishing features (step/operation 406) used for generating scan-based feature identifiers to ensure reliability of identifying hardware device under various working conditions. In some embodiments, determining the robustness of the scan-based feature identifier comprises characterizing material variances that are caused by real-world environmental and/or operating conditions by analyzing hardware devices via one or more inspection modalities (e.g., THz-TDS), as disclosed herewith.

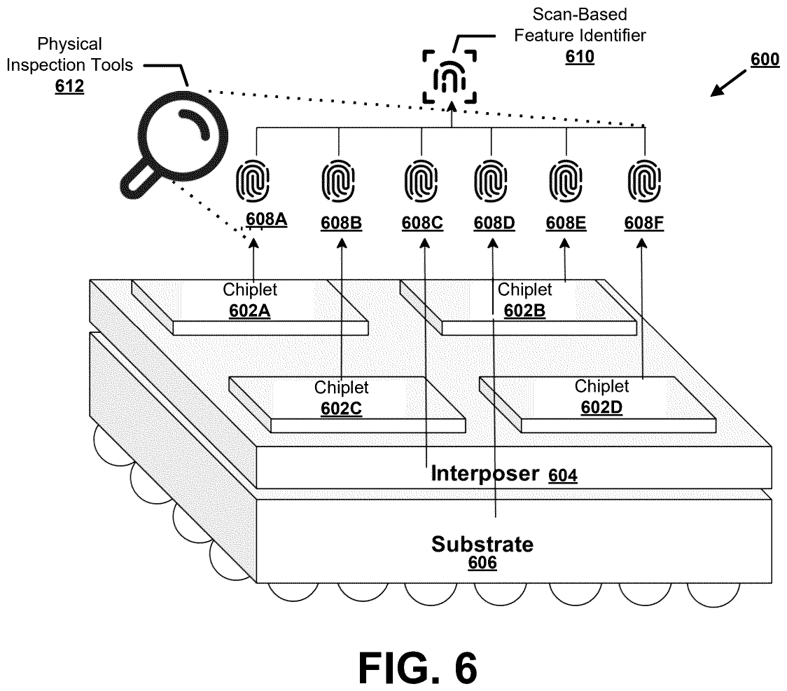

FIG. 6 depicts an operational example of analyzing a SiP 600 in accordance with some embodiments of the present disclosure. As depicted in FIG. 6, SiP 600 comprises a plurality of chiplets 602(A-D) that are coupled to an interposer 604 which is embedded on a substrate 606. The plurality of chiplets 602(A-D) may originate from a plurality of fabrication facilities, while the substrate 606 and the interposer 604 may be sourced from other origins. Thus, establishing identification of the individual components of SiP 600 that is accessible to an authorized entity may be important to secure the system-level design associated with SiP 600 against different forms of counterfeiting. In some embodiments, one or more digital fingerprints 608(A-F) comprising distinguishing features that are associated with corresponding one or more components (e.g., chiplets 602(A-D), interposer 604, and/or substrate 606) of the SiP 600 are generated based on measurement data obtained from physical inspection tools 612. In some embodiments, the physical inspection tools 612 comprises using THz-TDS to scan individual components in SiP 600. The one or more digital fingerprints 608(A-F) are used to generate a scan-based feature identifier 610 for the SiP 600.

### CONCLUSION

It should be understood that the examples and embodiments described herein are for illustrative purposes only and that various modifications or changes in light thereof will be suggested to persons skilled in the art and are to be included within the spirit and purview of this application.

Many modifications and other embodiments of the present disclosure set forth herein will come to mind to one skilled in the art to which the present disclosures pertain having the benefit of the teachings presented in the foregoing descriptions and the associated drawings. Therefore, it is to be understood that the present disclosure is not to be limited to the specific embodiments disclosed and that modifications and other embodiments are intended to be included within the scope of the appended claim concepts. Although specific terms are employed herein, they are used in a generic and descriptive sense only and not for purposes of limitation.

1. A computer-implemented method comprising:
determining, by one or more processors, one or more inspection modalities for inspecting a hardware device;
receiving, by the one or more processors, measurement data that is associated with a performance of one or more inspections on the hardware device based on the one or more inspection modalities;
determining, by the one or more processors, one or more distinguishing features based on the measurement data, wherein the one or more distinguishing features correspond to one or more hardware components of the hardware device; and
generating, by the one or more processors, a scan-based feature identifier for the hardware device based on the one or more distinguishing features.

2. The computer-implemented method of claim 1 further comprising determining one or more refinements to the one or more distinguishing features based on (i) a collision rate of the scan-based feature identifier with respect to another hardware device or (ii) robustness of the scan-based feature identifier with respect to one or more of aging, wear, or one or more environmental factors.

3. The computer-implemented method of claim 1, wherein the one or more inspection modalities comprise terahertz imaging, thermoreflectance imaging, acoustic imaging/microscopy, 2D or 3D X-ray computed tomography, energy-dispersive X-ray spectroscopy, or Raman spectroscopy.

4. The computer-implemented method of claim 1, wherein the performance of the one or more inspections comprises determining, using terahertz time-domain spectroscopy, integrated circuit packaging material characteristics associated with the hardware device.

5. The computer-implemented method of claim 1, wherein the measurement data comprises imaging or spectroscopic data that is associated with a through-silicon via, a micro-bump, or a region of interest within the one or more hardware components.

6. The computer-implemented method of claim 1, wherein the one or more distinguishing features comprise grain size and orientation in polycrystalline materials, defect types and densities, and variations in dopant distributions.

7. The computer-implemented method of claim 1 further comprising quantifying microstructural defects, material composition variations, or unique characteristics that are associated with fabrication of the hardware device.

8. The computer-implemented method of claim 1, wherein determining the one or more distinguishing features comprises:
determining one or more layer thicknesses of the hardware device based on the measurement data;
determining one or more refractive indices of the hardware device based on the measurement data; and
comparing the one or more refractive indices between authentic and counterfeit samples of the hardware device.

9. The computer-implemented method of claim 1, wherein determining the one or more distinguishing features comprises:
generating, using an unsupervised machine learning algorithm, one or more clusters of the measurement data; and
labeling the one or more distinguishing features based on authenticity associated with the one or more clusters.

10. The computer-implemented method of claim 1, wherein generating the scan-based feature identifier comprises transforming the one or more distinguishing features of the hardware device into one or more unique digital signatures or fingerprints.

11. The computer-implemented method of claim 1, wherein generating the scan-based feature identifier comprises generating a plurality of tiered scan-based feature identifiers for a plurality of hardware levels that are associated with the hardware device.

12. A system comprising:
one or more processors and
at least one memory storing processor-executable instructions that, when executed by any of the one or more processors, causes the one or more processors to perform operations comprising:
determining one or more inspection modalities for inspecting a hardware device;
receiving measurement data that is associated with a performance of one or more inspections on the hardware device based on the one or more inspection modalities;
determining one or more distinguishing features based on the measurement data, wherein the one or more distinguishing features correspond to one or more hardware components of the hardware device; and
generating a scan-based feature identifier for the hardware device based on the one or more distinguishing features.

13. The system of claim 12, wherein the operations further comprise determining one or more refinements to the one or more distinguishing features based on (i) a collision rate of the scan-based feature identifier with respect to another hardware device or (ii) robustness of the scan-based feature identifier with respect to one or more of aging, wear, or one or more environmental factors.

14. The system of claim 12, wherein the one or more inspection modalities comprise terahertz imaging, thermoreflectance imaging, acoustic imaging/microscopy, 2D or 3D X-ray computed tomography, energy-dispersive X-ray spectroscopy, or Raman spectroscopy.

15. The system of claim 12, wherein the performance of the one or more inspections comprises determining, using terahertz time-domain spectroscopy, integrated circuit packaging material characteristics associated with the hardware device.

16. The system of claim 12, wherein the measurement data comprises imaging or spectroscopic data that is associated with a through-silicon via, a micro-bump, or a region of interest within the one or more hardware components.

17. The system of claim 12, wherein the one or more distinguishing features comprise grain size and orientation in polycrystalline materials, defect types and densities, and variations in dopant distributions.

18. The system of claim 12, wherein the operations further comprise quantifying microstructural defects, material composition variations, or unique characteristics that are associated with fabrication of the hardware device.

19. The system of claim 12, wherein to determine the one or more distinguishing features, the operations further comprise:
determining one or more layer thicknesses of the hardware device based on the measurement data;
determining one or more refractive indices of the hardware device based on the measurement data; and
comparing the one or more refractive indices between authentic and counterfeit samples of the hardware device.

20. One or more non-transitory computer-readable storage media including instructions that, when executed by one or more processors, cause the one or more processors to perform operations comprising:
determining one or more inspection modalities for inspecting a hardware device;
receiving measurement data that is associated with a performance of one or more inspections on the hardware device based on the one or more inspection modalities;
determining one or more distinguishing features based on the measurement data, wherein the one or more distinguishing features correspond to one or more hardware components of the hardware device; and
generating a scan-based feature identifier for the hardware device based on the one or more distinguishing features.
